(19) United States
(12) Patent Application Publication
(10) Pub. No.: US 2025/0393304 A1
(43) Pub. Date: Dec. 25, 2025

(54) DISPLAY SUBSTRATE, DISPLAY PANEL, AND DISPLAY APPARATUS

(71) Applicants: Wuhan BOE Optoelectronics Technology Co., Ltd., Wuhan, Hubei (CN); BOE Technology Group Co., Ltd., Beijing (CN)

(72) Inventors: Qi CHEN, Beijing (CN); Mengbo PAN, Beijing (CN); Wei WU, Beijing (CN); Junfeng DAI, Beijing (CN); Dang ZHANG, Beijing (CN); Xiang LIU, Beijing (CN); Taohe ZHU, Beijing (CN); Hao ZHANG, Beijing (CN); Yiyi ZHANG, Beijing (CN); Yichen ZHOU, Beijing (CN); Yuan TONG, Beijing (CN)

(21) Appl. No.: 18/881,259

(22) PCT Filed: Mar. 13, 2024
(86) PCT No.: PCT/CN2024/081522

§ 371 Date: Jan. 3, 2025

(30) Foreign Application Priority Data
Apr. 28, 2023 (CN) 202310478862.4

(51) Int. Cl. H10D 86/40; G02F 1/1337; G02F 1/1339; G02F 1/1362

(52) U.S. Cl. CPC H10D 86/441; G02F 1/133723; G02F 1/13394; G02F 1/136286

(57) ABSTRACT

A display substrate includes a display area and a non-display area surrounding the display area. The non-display area includes a fan-shaped area between the display area and a side edge of the display substrate. The fan-shaped area includes: multiple first wiring lines extending along a direction parallel to an extending direction of the side edge, and multiple second wiring lines extending along a direction perpendicular to the extending direction. The multiple first wiring lines and the multiple second wiring lines are interconnected to form multiple grid units. In each grid unit, a first distance between two first wiring lines and a second distance between two second wiring lines are both less than a preset value.

### CROSS-REFERENCE TO RELATED APPLICATION

This application is a national phase entry under 35 U.S.C. § 371 of International Application No. PCT/CN2024/081522, filed on Mar. 13, 2024, which claims priority to Chinese Patent Application No. 202310478862.4, filed with the China National Intellectual Property Administration on Apr. 28, 2023 and entitled “Display Substrate, Display Panel and Display Apparatus”, the entire contents of which are incorporated herein by reference.

### TECHNICAL FIELD

The present disclosure relates to the field of display technology, and in particular to a display substrate, a display panel and a display apparatus.

### BACKGROUND

As people's requirements for image quality of LCD screens become higher and higher, improving display quality of products has become a top priority for panel companies. How to solve the problem of yellowing in local areas of LCD panels has become the key to improving image quality.

### SUMMARY

The present disclosure provides a display substrate, a display panel and a display apparatus.

The present disclosure provides a display substrate, including: a display area and a non-display area surrounding the display area.

The non-display area includes a fan-shaped area between the display area and a side edge of the display substrate.

The fan-shaped area includes: a plurality of first wiring lines extending along a direction parallel to an extending direction of the side edge, and a plurality of second wiring lines extending along a direction perpendicular to the extending direction. The plurality of first wiring lines and the plurality of second wiring lines are interconnected to form a plurality of grid units. A first spacing between two of the first wiring lines and a second spacing between two of the second wiring lines in the grid unit are both less than a preset value.

Optionally, in embodiments of the present disclosure, the preset value ranges from 56 μm to 127 μm.

Optionally, in embodiments of the present disclosure, the first spacing is smaller than the second spacing.

Optionally, in embodiments of the present disclosure, a line width of the first wiring line is equal to a line width of the second wiring line. The line width ranges from 7 μm to 8 μm.

The first spacing ranges from 35 μm to 36 μm. The second spacing ranges from 70 μm to 72 μm.

Optionally, in embodiments of the present disclosure, a first line width of the first wiring line is larger than a second line width of the second wiring line.

Optionally, in embodiments of the present disclosure, the first line width ranges from 14 μm to 16 μm. The second line width ranges from 7 μm to 9 μm. The first spacing ranges from 19 μm to 21 μm. The second spacing ranges from 69 μm to 71 μm.

Optionally, in embodiments of the present disclosure, a third line width of the first wiring line is smaller than a fourth line width of the second wiring line.

Optionally, in embodiments of the present disclosure, the third line width ranges from 7 μm to 9 μm. The fourth line width ranges from 14 μm to 16 μm. The first spacing ranges from 35 μm to 37 μm. The second spacing ranges from 53 μm to 55 μm.

Optionally, in embodiments of the present disclosure, areas of figures enclosed by the plurality of grid units are equal.

Optionally, in embodiments of the present disclosure, the plurality of grid units include a first grid and a second grid. The area of a figure enclosed by the second grid is larger than the area of a figure enclosed by the first grid. The second grid at least partially overlaps with a support pillar arranged on an opposite substrate.

Optionally, in embodiments of the present disclosure, a length of the second grid along the extending direction ranges from 100 μm to 120 μm. A length of the second grid along a direction perpendicular to the extending direction ranges from 40 μm to 50 μm.

Optionally, in embodiments of the present disclosure, there are multiple second grids. The multiple second grids are evenly distributed at equal intervals along the extending direction.

Accordingly, embodiments of the present disclosure further provide a display panel.

The display panel includes the display substrate as described in any one of the above embodiments, an opposite substrate arranged opposite to the display substrate, and a plurality of support pillars arranged between the display substrate and the opposite substrate.

The plurality of support pillars include a partial support pillar located in the fan-shaped area. The area of a figure enclosed by the grid unit is smaller than the area of an orthographic projection of the partial support pillar on the display substrate.

Optionally, in embodiments of the present disclosure, the length of the orthographic projection along the extending direction is larger than the second spacing. The length of the orthographic projection along a direction perpendicular to the extending direction is larger than the first spacing.

Optionally, in embodiments of the present disclosure, the plurality of grid units include a first grid and a second grid. The area of a figure enclosed by the second grid is larger than the area of a figure enclosed by the first grid. The second grid at least partially overlaps with the partial support pillar.

Optionally, in embodiments of the present disclosure, the length of the second grid along the extending direction is smaller than the length of the orthographic projection along the extending direction. The length of the second grid along the direction perpendicular to the extending direction is smaller than the length of the orthographic projection along the direction perpendicular to the extending direction.

Accordingly, embodiments of the present disclosure further provide a display apparatus, including: a display panel as described in any one of the above embodiments.

### BRIEF DESCRIPTION OF DRAWINGS

FIG. 1 is a schematic diagram showing yellowing at a fixed position of the Data Pad (DP) side of a liquid crystal panel product having a polyimide (PI) film thickness of 1000 angstroms in the related art.

FIG. 2 is a schematic diagram of the PI droplet coating positions on the Thin Film Transistor (TFT) side of the liquid crystal panel product shown in FIG. 1.

FIG. 3 illustrates Atomic Force Microscopy (AFM) height graphics at different PI aggregation positions on the TFT side of the liquid crystal panel product shown in FIG. 1.

FIG. 4 is a partial schematic diagram of box alignment in the liquid crystal panel product shown in FIG. 1.

FIG. 5 is a schematic diagram of a top view of a display substrate provided in an embodiment of the present disclosure.

FIG. 6 is an enlarged view of the fan-shaped area in FIG. 5.

FIG. 7 is a schematic diagram of a top view of a display substrate provided in an embodiment of the present disclosure.

FIG. 8 is an enlarged view of the fan-shaped area in FIG. 5.

FIG. 9 is an enlarged view of the fan-shaped area in FIG. 5.

FIG. 10 is an enlarged view of the fan-shaped area in FIG. 5.

FIG. 11 is an enlarged view of the fan-shaped area in FIG. 5.

FIG. 12 is a schematic diagram of a top view of a display panel provided in an embodiment of the present disclosure.

FIG. 13 is a schematic diagram of a cross-sectional structure along the direction indicated by MM in FIG. 12.

FIG. 14 is a schematic diagram of a top view of a display panel provided in an embodiment of the present disclosure.

### DETAILED DESCRIPTION

In order to make the purpose, technical solution and advantages of the embodiments of the present disclosure more clear, the technical solution of the embodiments of the present disclosure will be clearly and completely described below in conjunction with the drawings of the embodiments of the present disclosure. Obviously, the described embodiments are only part of the embodiments of the present disclosure, rather than all the embodiments.

Furthermore, the embodiments in the present disclosure and the features in the embodiments may be combined with each other without conflict. Based on the described embodiments of the present disclosure, all other embodiments obtained by those of ordinary skill in the art without creative work are within the scope of protection of the present disclosure.

Unless otherwise defined, technical or scientific terms used in the present disclosure should have the common meanings understood by a person having ordinary skills in the field to which the present disclosure belongs. The words “include” or “comprise” and the like used in the present disclosure mean that the elements or objects preceding the words include the elements or objects listed after the words and their equivalents, but do not exclude other elements or objects.

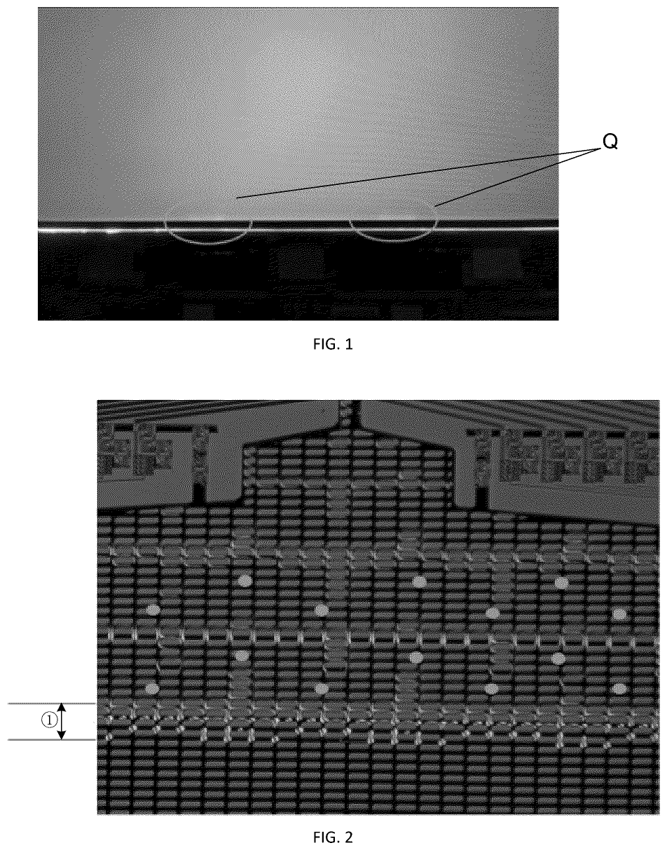

In the related art, the inventor discovers through actual research that during the development and mass production of 65-inch 4K 144 Hz LCD products, yellowing at the data pad (DP) side under the L127 screen occurs in the module segment, which is a serious phenomenon with a high rate of occurrence, and severely affects the display quality and out-going grade. FIG. 1 is a schematic diagram showing yellowing at a fixed position (as shown in area Q in FIG. 1) of the DP side of a liquid crystal panel product having a PI (polyimide) film thickness of 1000 angstroms. By measuring the liquid crystal cell gap (CG) at the yellowing position, it is found that the CG value corresponding to the yellowing position is higher than that at other positions, indicating that the difference in cell gap may be the cause of the yellowing. By disassembling the screen and observing it with a microscope, it is found that the yellowing position is exactly in the fan-shaped metal wiring area F on the thin film transistor (TFT) side 01 of the liquid crystal panel product. FIG. 2 is a schematic diagram of the PI droplet coating positions on the TFT side 01 of the liquid crystal panel product. It can be clearly seen that the fan-shaped metal wiring area F is divided into bright and dark areas, indicating that the PI droplet diffusion in the fan-shaped metal wiring area F is not uniform. In FIG. 2, \textcircled{1} represents the PI aggregation boundary. The scattered small dots in FIG. 2 are PI droplets spit out by the PI nozzle (Nozzle). The dark area is the relatively uniform diffusion area of PI droplets, and the bright area is the PI droplet diffusion and aggregation area. Further, it can be found that the PI aggregation is the most serious at the boundary.

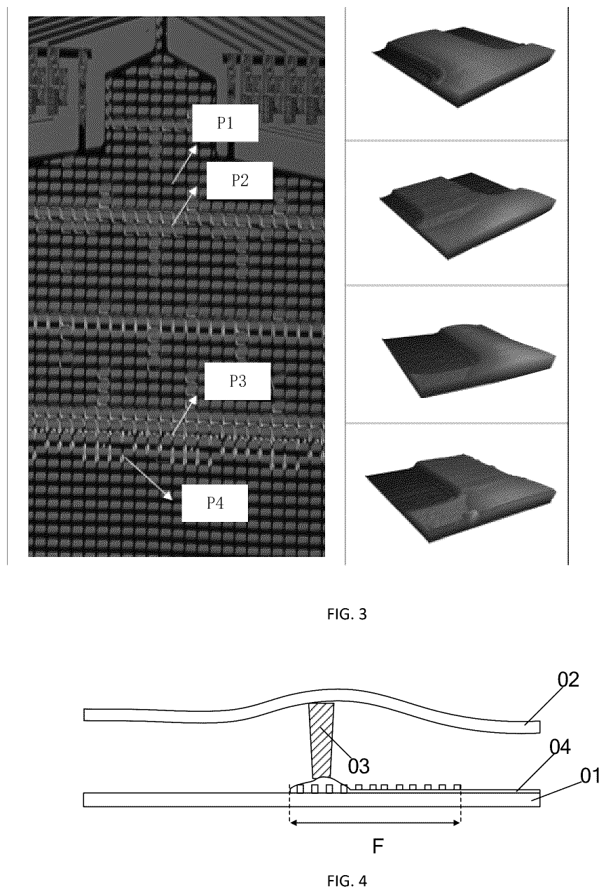

In order to further verify that the yellowing is caused by the difference in film thickness due to PI aggregation, the inventors select a liquid crystal panel product with a PI film thickness of 1000 angstroms and severe yellowing for research. AFM film thickness measurements are performed at different positions (e.g., P1, P2, P3 and P4) of the fan-shaped metal wiring area F on the TFT side 01, to obtain Atomic force microscope (AFM) height graphics at different PI aggregation positions on the TFT side 01 as shown in FIG. 3. Combined with the results shown in FIG. 3, it is found that the film thickness is the smallest at P1. The PI droplets fall and diffuse more evenly at P1. The film thickness at P2 is slightly larger than that at P1. P2 is between droplets and there will be slight aggregation at P2. The PI film thickness is the largest at P3 and P4. This is because the PI droplets gradually become smaller during the outward diffusion process, stop diffusing under the action of surface tension, and form bulges after solidification, resulting in an abnormal cell gap at P3 and P4. In addition, the support pillar (PS Bar) 03 on the color filter (CF) side 02 at P4 is observed under a microscope, and it is found that the orthographic projection of the PS Bar on the TFT side 01 overlaps with the boundary where PI aggregation is the most serious. In FIG. 4, reference number 04 refers to an alignment layer formed by PI droplets. Based on the above analysis, the inventors believe that the yellowing on the DP side is caused by the poor diffusion and easy to aggregation of PI in the fan-shaped metal wiring area F, and by the overlapping of PI with the PS Bar. It can be seen that the existing PI droplets aggregate in the fan-shaped metal wiring area F on the TFT side 01. After solidification of the PI droplets, the PI film is thickening. After box alignment, the PI aggregation area on the TFT side 01 partially or completely overlaps with the PS Bar 03 occupying area on the CF side 02, resulting in an increase in the liquid crystal cell gap in the corresponding area and a yellowing problem in a local area. The box alignment is shown in FIG. 4.

In view of this, embodiments of the present disclosure provide a display substrate, a display panel and a display apparatus for solving the yellowing problem on the DP side.

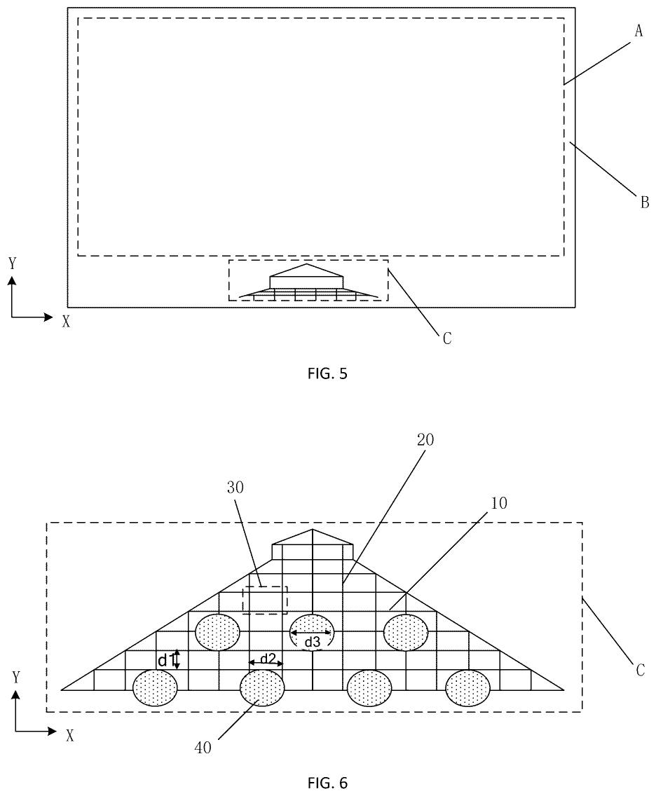

As shown in FIG. 5 and FIG. 6, FIG. 5 is a schematic diagram of a top view of a display substrate provided in an embodiment of the present disclosure, and FIG. 6 is an enlarged view of a fan-shaped area C in FIG. 5.

In some embodiments, the display substrate includes: a display area A and a non-display area B surrounding the display area A. The non-display area B includes a fan-shaped area C located between the display area A and a side edge of the display substrate.

The fan-shaped area C includes: a plurality of first wiring lines 10 extending along a direction parallel to an extending direction of the side edge, and a plurality of second wiring lines 20 extending along a direction perpendicular to the extending direction. The plurality of first wiring lines 10 and the plurality of second wiring lines 20 are interconnected to form a plurality of grid units 30. A first spacing between two of the first wiring lines 10 and a second spacing between two of the second wiring lines 20 in each of the grid units 30 are both less than a preset value.

In an implementation process, the display substrate includes a display area A and a non-display area B surrounding the display area A. The non-display area B includes a fan-shaped area C located between the display area A and a side edge of the display substrate. Exemplarily, there are multiple fan-shaped areas C. The fan-shaped area C includes: a plurality of first wiring lines 10 extending along a direction parallel to an extending direction of the side edge, and a plurality of second wiring lines 20 extending along a direction perpendicular to the extending direction. Still referring to FIG. 5, the direction indicated by arrow X is the extending direction of the side edge of the display substrate. The direction indicated by arrow Y is the direction perpendicular to the extending direction of the side edge. Of course, the number of the plurality of first wiring lines 10 and the number of the plurality of second wiring lines 20 can be set according to actual application requirements and are not limited here.

Moreover, the plurality of first wiring lines 10 and the plurality of second wiring lines 20 are interconnected to form a plurality of grid units 30. The specific of the plurality of grid units 30 can be set according to actual application requirements and is not limited here. In addition, the first spacing between two first wiring lines 10 and the second spacing between two second wiring lines 20 in each grid unit 30 are both smaller than a preset value. Exemplarily, the preset value is close to the diameter of the droplet 40 used to prepare the alignment layer. In this way, under the premise that the diameter of the droplet 40 used to prepare the alignment layer is certain, by adjusting the first wiring lines 10 and the second wiring lines 20 in a single grid unit 30, for example, increasing the first spacing between the two first wiring lines 10 and the second spacing between the two second wiring lines 20 as much as possible, the first spacing and the second spacing can be close to the diameter of the droplet 40, and the surface area of the single grid unit 30 in the fan-shaped area C is increased, thereby reducing the possibility of aggregation of the droplets 40 used to prepare the alignment layer. In exemplary embodiments shown in FIG. 6, d1 represents a first spacing between two first wiring lines 10, d2 represents a second spacing between two second wiring lines 20, and d3 represents a diameter of a droplet 40. In an actual process of preparing a fan-shaped area, the relationship d1<d3 and d2<d3 is satisfied. As a result, in the subsequent process of preparing the alignment layer, the droplets 40 for preparing the alignment layer can be dropped into the central area of the corresponding grid unit 30, thereby avoiding the yellowing problem caused by the aggregation of the droplets 40 for preparing the alignment layer.

It should be noted that the alignment layer on the display substrate extends from the display area A to the non-display area B. Exemplarily, the alignment layer may be a polyimide (PI) film. In the subsequent process of using the display substrate to prepare a display panel, the pre-set alignment layer can be used to make the liquid crystal molecules in the liquid crystal layer of the display panel tilt at a preset angle, thereby adjusting the light transmittance and ensuring the display effect of the prepared display panel.

In embodiments of the present disclosure, the preset value ranges from 56 μm to 127 μm. In an actual process of preparing the display substrate, the first spacing between two first wiring lines 10 and the second spacing between two second wiring lines 20 in the fan-shaped area C can be set according to the range of the diameter of the droplets 40 used to prepare the alignment layer. The values of the first spacing and the second spacing can be set according to actual application requirements and are not limited here. Exemplarily, the diameter of the droplet 40 used to prepare the alignment layer is 80 μm.

In embodiments of the present disclosure, the first spacing is smaller than the second spacing. In this way, it is convenient to align the grid units 30 in the fan-shaped area C with the cuboid support pillars arranged on the opposite substrate.

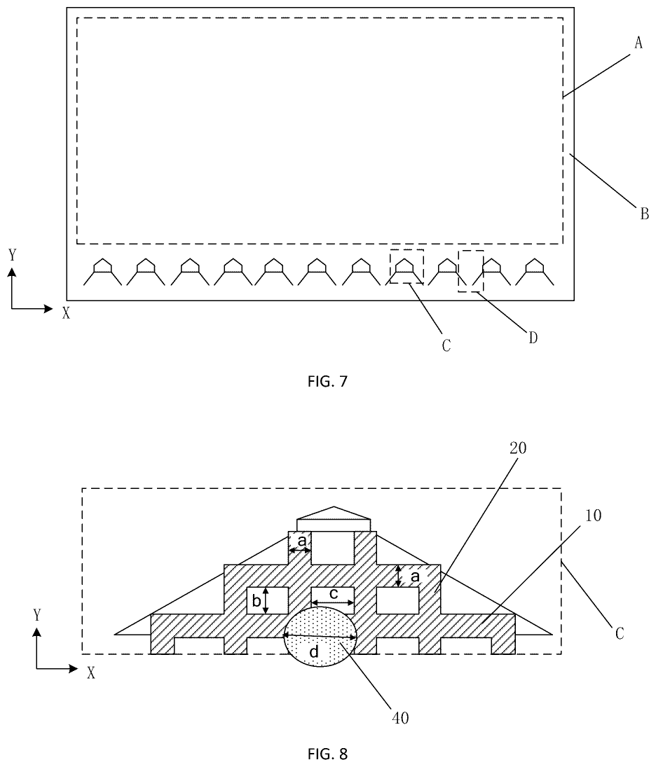

In embodiments of the present disclosure, the non-display area B further includes non-fan-shaped areas D arranged alternately with the fan-shaped areas C along the extending direction of the side edge of the display substrate. The non-fan-shaped area D includes a plurality of third wiring lines extending in the same direction. The fan-shaped area C is used to introduce a common voltage. The non-fan-shaped area D is used to externally connect a source-drain signal voltage and a gate signal voltage. Exemplarily, FIG. 7 is a schematic diagram showing one distribution of the display area A, the non-display area B, the fan-shaped areas C, and the non-fan-shaped areas D. Of course, the various areas can also be distributed according to actual application needs, which is not limited here. The setting of the third wiring lines in the non-fan-shaped area D may refer to the implementation in the related art, which will not be described in detail here.

In embodiments of the present disclosure, the wiring lines within the fan-shaped area C may be arranged in the following ways, but is not limited to the following ways.

In exemplary embodiments, as shown in FIG. 8, the line width of each of the first wiring lines 10 is equal to the line width of each of the second wiring lines 20, and the line width ranges from 7 μm to 8 μm.

Still referring to the exemplary embodiments shown in FIG. 8, the line width of each first wiring line 10 and the line width of each second wiring line 20 are both ‘a’. The value of ‘a’ ranges from 7 μm to 8 μm. Exemplarily, ‘a’ is 7.5 μm.

In exemplary embodiments, under the premise that the line widths of each first wiring line 10 and each second wiring line 20 are equal, the first spacing ranges from 35 μm to 36 μm, and the second spacing ranges from 70 μm to 72 μm.

Still referring to FIG. 8, ‘b’ represents a first spacing between two first wiring lines 10 in each grid unit 30, and ‘c’ represents a second spacing between two second wiring lines 20 in each grid unit 30, and b<c. In an actual preparation process, ‘b’ ranges from 35 μm to 36 μm, and ‘c’ ranges from 70 μm to 72 μm. Exemplarily, ‘b’ is 35.5 μm and ‘c’ is 71 μm.

In exemplary embodiments shown in FIG. 8, in the subsequent process of preparing the alignment layer, the inkjet head evenly drips PI droplets 40 according to a set pattern. When the droplet 40 first contacts the surface of the display substrate, it is semi-spherical, and its diameter is ‘d’. In these exemplary embodiments, d>b, and d>c need to be satisfied.

Subsequently, the PI droplets 40 are diffused, film-formed, pre-cured and cured to form a PI alignment layer. In an implementation process, the preparation process of the alignment layer can refer to the implementation in the related art, which will not be described in detail here.

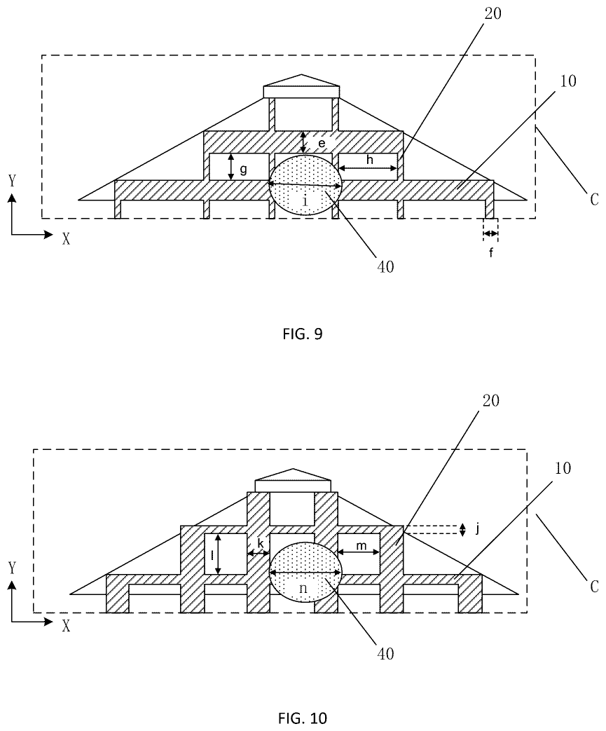

In exemplary embodiments, as shown in FIG. 9, the first line width of each first wiring line 10 is greater than the second line width of each second wiring line 20.

Exemplarily, the first line width ranges from 14 μm to 16 μm. The second line width ranges from 7 μm to 9 μm. The first spacing ranges from 19 μm to 21 μm. The second spacing ranges from 69 μm to 71 μm.

Still in combination with the exemplary embodiments shown in FIG. 9, ‘e’ represents the first line width of each first wiring line 10, ‘f’ represents the second line width of each second wiring line 20, and e>f. In an actual preparation process, ‘e’ ranges from 14 μm to 16 μm. ‘f’ ranges from 7 μm to 9 μm. Exemplarily, ‘e’ is 15 μm and ‘f’ is 8 μm. ‘g’ represents a first spacing between two first wiring lines 10 in each grid unit 30, ‘h’ represents a second spacing between two second wiring lines 20 in each grid unit 30, and g<h. In an actual preparation process, ‘g’ ranges from 19 μm to 21 μm, and ‘h’ ranges from 69 μm to 71 μm. Exemplarily, ‘g’ is 20 μm and ‘c’ is 70 μm.

In exemplary embodiments shown in FIG. 9, in the subsequent process of preparing the alignment layer, the inkjet head evenly drips PI droplets 40 according to a set pattern. When the droplet 40 first contacts the surface of the display substrate, it is semi-spherical, and its diameter is ‘i’. Illustratively, i>e and i>f. Subsequently, the PI droplets 40 are diffused, film-formed, pre-cured and cured to form a PI alignment layer. In an implementation process, the preparation process of the alignment layer can refer to the implementation in the related art, which will not be described in detail here.

In exemplary embodiments, as shown in FIG. 10, a third line width of each first wiring line 10 is smaller than a fourth line width of each second wiring line 20.

Exemplarily, the third line width ranges from 7 μm to 9 μm. The fourth line width ranges from 14 μm to 16 μm. The first spacing ranges from 35 μm to 37 μm. The second spacing ranges from 53 μm to 55 μm.

Still in combination with the exemplary embodiments shown in FIG. 10, ‘j’ represents the third line width of each first wiring line 10, ‘k’ represents the fourth line width of each second wiring line 20′, and j<k. In an actual preparation process, ‘j’ ranges from 7 μm to 9 μm, and ‘k’ ranges from 14 μm to 16 μm. Exemplarily, ‘j’ is 8 μm and ‘k’ is 15 μm. ‘I’ represents a first spacing between two first wiring lines 10 in each grid unit 30, ‘m’ represents a second spacing between two second wiring lines 20 in each grid unit 30, and km. In an actual preparation process, ‘l’ ranges from 35 μm to 37 μm, and ‘m’ ranges from 53 μm to 55 μm. Exemplarily, ‘l’ is 36 μm and ‘m’ is 54 μm.

In exemplary embodiments shown in FIG. 10, in the subsequent process of preparing the alignment layer, the inkjet head evenly drips PI droplets 40 according to a set pattern. When the droplet 40 first contacts the surface of the display substrate, it is semi-spherical, and its diameter is ‘n’. Illustratively, n>j, and n>k. Subsequently, the PI droplets 40 are diffused, film-formed, pre-cured and cured to form a PI alignment layer. In an implementation process, the preparation process of the alignment layer can refer to the implementation in the related art, which will not be described in detail here.

It should be noted that in exemplary embodiments shown in FIGS. 8 to 10, according to actual application needs, the line width of the first wiring line 10 and the line width of the second wiring line 20 in a single grid unit 30 can be reduced, so that the first spacing between two adjacent first wiring lines 10 and the second spacing between two adjacent second wiring lines 20 are increased, thereby increasing the surface area of a single grid unit 30 in the fan-shaped area C, reducing the possibility of aggregation of droplets 40 used to prepare the alignment layer, and thus avoiding the problem of yellowing on the DP side.

In embodiments of the present disclosure, the areas of the figures enclosed by the multiple grid units 30 are equal.

Still referring to FIGS. 8 to 10, a single grid unit 30 among the multiple grid units 30 is repeatedly arranged in the fan-shaped area C. Accordingly, the corresponding line widths of respective grid units 30 are equal, the spacing between two first wiring lines 10 of respective grid units 30 is equal, and the spacing between two second wiring lines 20 of respective grid units 30 is equal. In this way, the areas of the figures enclosed by the multiple grid units 30 are equal. In this way, the uniformity of force during the subsequent addition of PI droplets 40 into the grid units 30 is ensured, and the uniformity of the film thickness of the alignment layer is ensured.

In embodiments of the present disclosure, the multiple grid units 30 include a first grid 31 and a second grid 32. The area of the figure enclosed by the second grid 32 is larger than the area of the figure enclosed by the first grid 31. The second grid 32 at least partially overlaps with the support pillar arranged on the opposite substrate.

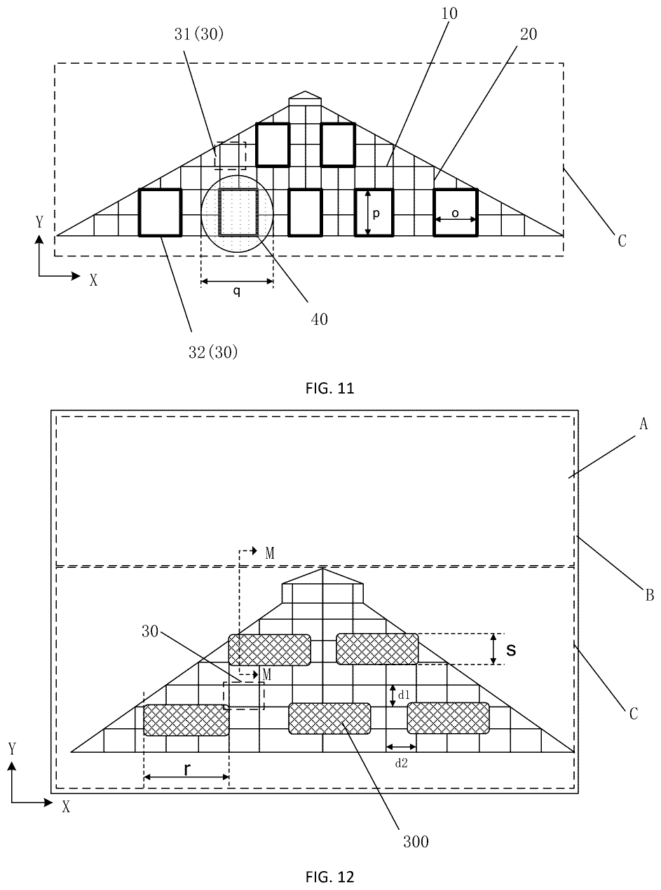

In exemplary embodiments, in combination with FIG. 11, the plurality of grid units 30 include first grids 31 and second grids 32. The area of the figure enclosed by the second grid 32 is larger than the area of the figure enclosed by the first grid 31. That is, the plurality of grid units 30 arranged in the fan-shaped area C include grids of two sizes of areas. The second grid 32 at least partially overlaps with the support pillar disposed on the opposite substrate.

Still in combination with the exemplary embodiments shown in FIG. 11, the length of the second grid 32 along the extending direction ranges from 100 μm to 120 μm, and the length of the second grid 32 along a direction perpendicular to the extending direction ranges from 40 μm to 50 μm.

Still in combination with FIG. 11, ‘o’ represents the length of the second grid 32 along the extending direction of the side edge of the display substrate, and ‘p’ represents the length of the second grid 32 along a direction perpendicular to the extending direction. The length ‘o’ ranges from 100 μm to 120 μm, and p ranges from 40 μm to 50 μm. Exemplarily, ‘o’ is 110 μm and p is 45 μm.

Still in combination with the exemplary embodiments shown in FIG. 11, in the subsequent process of preparing the alignment layer, the inkjet head evenly drips PI droplets 40 according to a set pattern. When the droplet 40 first contacts the surface of the display substrate, it is semi-spherical, and its diameter is ‘q’. Illustratively, q>o, and q>p. Subsequently, the PI droplets 40 are diffused, film-formed, pre-cured and cured to form a PI alignment layer.

In an implementation process, the preparation process of the alignment layer can refer to the implementation in the related art, which will not be described in detail here.

In embodiments of the present disclosure, still in combination with FIG. 11, there are multiple second grids 32. The multiple second grids 32 are evenly distributed at equal intervals along the extending direction.

In the exemplary embodiments shown in FIG. 11, the number of the second grids 32 can be set according to actual application requirements, which is not limited here. In addition, the multiple second grids 32 are evenly distributed at equal intervals along the extending direction of the side edge of the display substrate, which ensures the uniformity of force in the subsequent process of dripping PI droplets 40 into the multiple second grids 32 and the uniformity of the film thickness of the alignment layer.

It should be noted that, in addition to setting the first wiring lines 10 and the second wiring lines 20 in the fan-shaped area C in the manner shown above, the structural parameters of the relevant wiring lines in the fan-shaped area C can also be set according to actual application requirements, which is not limited here.

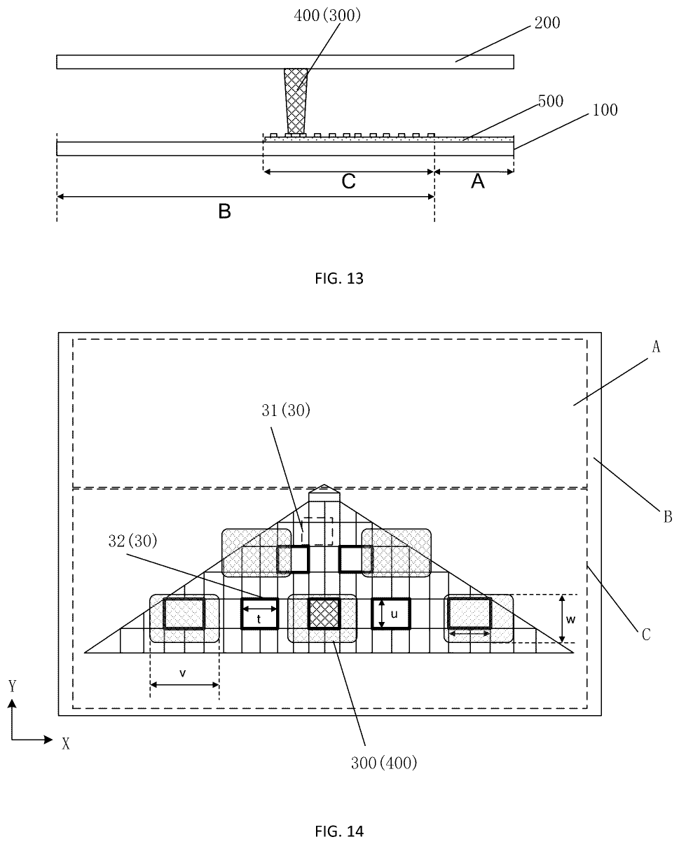

Based on the same disclosed concept, as shown in FIG. 12 and FIG. 13, FIG. 12 is a schematic diagram of a top view of a display panel provided in an embodiment of the present disclosure, and FIG. 13 is a schematic diagram of a cross-sectional structure along the direction indicated by MM in FIG. 12.

In some embodiments, the display panel includes: the display substrate 100 as described in any of the above embodiments, an opposite substrate 200 disposed opposite to the display substrate 100, and a plurality of support pillars 300 disposed between the display substrate 100 and the opposite substrate 200.

The plurality of support pillars 300 include partial support pillar(s) 400 located in the fan-shaped area(s) C. The area of the figure enclosed by each grid unit 30 is smaller than the area of the orthographic projection of the partial support pillar 400 on the display substrate 100.

In an implementation process, the plurality of support pillars 300 arranged between the display substrate 100 and the opposite substrate 200 include partial support pillar(s) 400 located in the fan-shaped area(s) C. The number of the plurality of support pillars 300 and the partial support pillar(s) 400 can be set according to actual application needs and is not limited here. Since the grid units 30 within the fan-shaped area C reduce to a certain extent the possibility of aggregation of the droplets 40 used to prepare the alignment layer (the reference numeral 500 in FIG. 13 indicates the alignment layer formed by the droplets 40), when the area of the figure enclosed by each grid unit 30 within the fan-shaped area C is set to be smaller than the area of the orthographic projection of partial support pillar 400 on the display substrate 100, even if the support pillar 400 overlaps with the grid unit 30, the yellowing problem caused by the aggregation of the droplets 40 can still be effectively avoided. In addition, for other support pillars arranged outside the fan-shaped area(s) C, reference may be made to the implementation in the related art, which will not be described in detail here.

The principle of solving the problem by the display panel is similar to the principle of solving the problem by the display substrate 100. Therefore, the implementation of the display panel provided in the embodiments of the present disclosure may refer to the implementation of the display substrate 100 described above, and the repeated parts will not be repeated.

In embodiments of the present disclosure, the length of the orthographic projection of partial support pillar along the extending direction is greater than the second spacing, and the length of the orthographic projection of partial support pillar along a direction perpendicular to the extending direction is greater than the first spacing.

Still in combination with the exemplary embodiment shown in FIG. 12, ‘r’ represents the length of the orthographic projection of partial support pillar 400 on the display substrate 100 along the extending direction of the side edge of the display substrate 100. ‘s’ represents the length of the orthographic projection of partial support pillar 400 on the display substrate 100 along a direction perpendicular to the extending direction of the side edge of the display substrate 100. ‘d1’ represents the first spacing, and ‘d2’ represents the second spacing. In an actual manufacturing process, each grid unit 30 is arranged according to the relationship r>d2 and s>d1. Of course, the size of each grid unit 30 can be set according to actual application requirements and is not limited here.

In embodiments of the present disclosure, in combination with the exemplary embodiments shown in FIG. 14, the multiple grid units 30 include first grids 31 and second grids 32. The area of the figure enclosed by the second grid 32 is larger than the area of the figure enclosed by the first grid 31. The second grid 32 at least partially overlaps with the partial support pillar 400. Of course, the number of the first grid 31 and the number of the second grid 32 both can be one or more, which is not limited here.

In embodiments of the present disclosure, the length of the second grid 32 along the extending direction is smaller than the length of the orthographic projection of partial support pillar along the extending direction. The length of the second grid 32 along a direction perpendicular to the extending direction is smaller than the length of the orthographic projection of partial support pillar along the direction perpendicular to the extending direction.

Still in combination with the exemplary embodiments shown in FIG. 14, ‘t’ represents the length of the second grid 32 along the extending direction of the side edge of the display substrate 100. ‘u’ represents the length of the second grid 32 along the direction perpendicular to the extending direction of the side edge of the display substrate 100. ‘v’ represents the length of the orthographic projection of partial support pillar 400 on the display substrate 100 along the extending direction of the side edge of the display substrate 100. ‘w’ represents the length of the orthographic projection of partial support pillar 400 on the display substrate 100 along the direction perpendicular to the extending direction of the side edge of the display substrate 100. In an actual manufacturing process, the second grid 32 is set according to the relationship t<v, and u<w. Of course, the sizes of the first grid 31 and the second grid 32 can be set according to the size of the partial support pillar 400 in actual applications, and are not limited here.

Based on the same inventive concept, embodiments of the present disclosure further provide a display apparatus, which includes the above-mentioned display panel provided by the embodiments of the present disclosure.

Since the principle of solving the problem by the display apparatus is similar to the principle of solving the problem by the above-mentioned display panel, the implementation of the display apparatus provided in the embodiments of the present disclosure can refer to the implementation of the above-mentioned display panel, and the repeated parts will not be repeated.

In some embodiments, the above-mentioned display apparatus provided by the embodiments of the present disclosure can be applied to any product or component with a display function, such as mobile phones, tablet computers, televisions, monitors, laptop computers, digital photo frames, navigators, smart watches, fitness wristbands, personal digital assistants, etc.

Optionally, the display apparatus provided in the embodiments of the present disclosure is a liquid crystal display screen. The liquid crystal display screen may include a backlight module and a display panel located at the light emitting side of the backlight module.

The display panel includes: a display substrate and an opposite substrate arranged opposite to each other, a liquid crystal layer located between the display substrate and the opposite substrate, a frame sealant surrounding the liquid crystal layer between the display substrate and the opposite substrate, a first alignment layer located on a side of the display substrate close to the liquid crystal layer, a second alignment layer located on a side of the opposite substrate close to the liquid crystal layer, a first polarizer located on a side of the display substrate away from the liquid crystal layer, and a second polarizer located on a side of the opposite substrate away from the liquid crystal layer, etc. The backlight module can be a direct-lit backlight module or an edge-lit backlight module. The backlight module may include a light source, stacked reflective sheets, a light guide plate, a diffusion sheet, a prism group, etc. The light source may be a light emitting diode (LED), such as a micro light emitting diode (Mini LED, Micro LED, etc.).

In some embodiments, the above-mentioned display apparatus provided by the embodiments of the present disclosure may include but is not limited to: a radio frequency unit, a network module, an audio output & input unit, a sensor, a display unit, a user input unit, an interface unit, a control chip and other components. Optionally, the control chip is a central processing unit, a digital signal processor, a system on chip (SoC), etc. For example, the control chip may also include a memory, a power module, etc., and realize power supply and signal input and output functions through additionally provided wires, signal lines, etc. For example, the control chip may also include hardware circuits, computer executable codes, etc. Hardware circuits may include conventional very large scale integration (VLSI) circuits or gate arrays and existing semiconductors such as logic chips, transistors, etc., or other discrete components. Hardware circuits may also include field programmable gate arrays, programmable array logic, programmable logic devices, etc.

In addition, those skilled in the art will appreciate that the above structure does not constitute a limitation on the above display apparatus provided in the embodiments of the present disclosure. In other words, the above display apparatus provided in the embodiments of the present disclosure may include more or fewer of the above components, or a combination of certain components, or different component arrangements. Although preferred embodiments of the present disclosure have been described, additional changes and modifications may be made to these embodiments once those skilled in the art are aware of the basic inventive concepts. Therefore, it is intended that the appended claims be interpreted as including the preferred embodiments as well as all changes and modifications that fall within the scope of the present disclosure.

Obviously, those skilled in the art can make various changes and modifications to the present disclosure without departing from the spirit and scope of the present disclosure. Thus, if these modifications and variations of the present disclosure fall within the scope of the claims of the present disclosure and their equivalent technologies, the present disclosure is also intended to include these modifications and variations.

1. A display substrate, comprising:
a display area, and
a non-display area surrounding the display area,
wherein the non-display area comprises:
a fan-shaped area between the display area and a side edge of the display substrate;
wherein the fan-shaped area comprises:
a plurality of first wiring lines extending along a direction parallel to an extending direction of the side edge, and
a plurality of second wiring lines extending along a direction perpendicular to the extending direction,
wherein the plurality of first wiring lines and the plurality of second wiring lines are interconnected to form a plurality of grid units; and a first spacing between two of the first wiring lines and a second spacing between two of the second wiring lines in the grid unit are both less than a preset value.

2. The display substrate according to claim 1, wherein the preset value ranges from 56 μm to 127 μm.

3. The display substrate according to claim 2, wherein the first spacing is smaller than the second spacing.

4. The display substrate according to claim 3, wherein a line width of the first wiring line is equal to a line width of the second wiring line, and the line width ranges from 7 μm to 8 μm.

5. The display substrate according to claim 4, wherein the first spacing ranges from 35 μm to 36 μm, and the second spacing ranges from 70 μm to 72 μm.

6. The display substrate according to claim 3, wherein a first line width of the first wiring line is larger than a second line width of the second wiring line.

7. The display substrate according to claim 6, wherein the first line width ranges from 14 μm to 16 μm, the second line width ranges from 7 μm to 9 μm, the first spacing ranges from 19 μm to 21 μm, and the second spacing ranges from 69 μm to 71 μm.

8. The display substrate according to claim 3, wherein a third line width of the first wiring line is smaller than a fourth line width of the second wiring line.

9. The display substrate according to claim 8, wherein the third line width ranges from 7 μm to 9 μm, the fourth line width ranges from 14 μm to 16 μm, the first spacing ranges from 35 μm to 37 μm, and the second spacing ranges from 53 μm to 55 μm.

10. The display substrate according to claim 1, wherein areas of figures enclosed by the plurality of grid units are equal.

11. The display substrate according to claim 1, wherein the plurality of grid units comprises:
a first grid, and
a second grid,
wherein an area of a figure enclosed by the second grid is larger than an area of a figure enclosed by the first grid, and the second grid at least partially overlaps with a support pillar arranged on an opposite substrate.

12. The display substrate according to claim 11, wherein a length of the second grid along the extending direction ranges from 100 μm to 120 μm, and a length of the second grid along a direction perpendicular to the extending direction ranges from 40 μm to 50 μm.

13. The display substrate according to claim 12, wherein there are a plurality of the second grids, and the plurality of the second grids are evenly distributed at equal intervals along the extending direction.

14. A display panel, comprising:
the display substrate according to claim 1,
an opposite substrate arranged opposite to the display substrate, and
a plurality of support pillars arranged between the display substrate and the opposite substrate;
wherein the plurality of support pillars comprise:
a partial support pillar in the fan-shaped area,
wherein an area of a figure enclosed by the grid unit is smaller than an area of an orthographic projection of the partial support pillar on the display substrate.

15. The display panel according to claim 14, wherein:
a length of the orthographic projection along the extending direction is larger than the second spacing; and
a length of the orthographic projection along a direction perpendicular to the extending direction is larger than the first spacing.

16. The display panel according to claim 15, wherein the plurality of grid units comprises:
a first grid, and
a second grid,
wherein an area of a figure enclosed by the second grid is larger than an area of a figure enclosed by the first grid, and the second grid at least partially overlaps with the partial support pillar.

17. The display panel according to claim 16, wherein:
a length of the second grid along the extending direction is smaller than the length of the orthographic projection along the extending direction; and
a length of the second grid along the direction perpendicular to the extending direction is smaller than the length of the orthographic projection shape along the direction perpendicular to the extending direction.

18. A display apparatus, comprising:
a display panel according to claim 14.
